(19) United States
(12) Patent Application Publication
(10) Pub. No.: US 2009/0225610 A1
(43) Pub. Date: Sep. 10, 2009

(54) INTEGRATED CIRCUIT THAT SELECTIVELY OUTPUTS SUBSETS OF A GROUP OF DATA BITS

(76) Inventors: Wolfgang Hokenmaier, Burlington, VT (US); Kevin Quinn, Richmond, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/042,797

(22) Filed: Mar. 5, 2008

(51) Int. Cl. G11C 29/00; H03K 19/00

(52) U.S. Cl. 365/201; 326/16

(57) ABSTRACT

An integrated circuit including an array of memory cells, a control circuit, and an output circuit. The array of memory cells is configured to provide a group of data bits. The control circuit is configured to provide a test mode signal. The output circuit is configured to receive the test mode signal and the group of data bits, where the output circuit selectively outputs smaller subsets of the group of data bits based on the test mode signal.

### BACKGROUND

Typically, a computer system includes a number of integrated circuit chips that communicate with one another to perform system applications. Often, the computer system includes a controller, such as a micro-processor, and one or more memory chips, such as random access memory (RAM) chips. The RAM chips can be any suitable type of RAM, such as dynamic RAM (DRAM), double data rate synchronous DRAM (DDR-SDRAM), low power SDRAM (LP-SDRAM), and/or pseudo static RAM (PSRAM). The controller and memory communicate with one another to perform system applications.

Some computer systems operate in mobile applications, such as cellular telephones and personal digital assistants (PDAs), which have limited space and power resources. Low power mobile RAM is a LP-SDRAM developed for mobile applications and CellularRAM is a PSRAM that offers static RAM (SRAM) pin and function compatibility. CellularRAM devices are drop-in replacements for most asynchronous low power SRAMs used in mobile applications, such as cellular telephones. Typically, a PSRAM includes DRAM that provides significant advantages in density and speed over traditional SRAM.

Usually, integrated circuits are tested in wafer form and after being diced and packaged. Integrated circuit testers have a limited number of resources available for testing components. Resource limitations include the number of driver/comparator circuits that judge the outputs from the components under test. If fewer resources are needed to test each component, more components can be tested in parallel, which decreases the per-unit cost of each component. Often, the number of memory components tested in parallel is limited by the number of outputs from each memory and the number of available driver/comparator pins.

A typical production memory test includes writing data to memory cells and reading the data back from the memory cells. The data read from the memory cells is compared to the data written into the memory cells to obtain pass/fail results that are compressed onto a limited number of outputs. In wafer testing, the compressed pass/fail results are output to a tester via a probecard having a limited number of probes, which increases the number of memories that can be tested in parallel. Failed bit locations, however, cannot be determined using the compressed results.

To obtain failed bit locations, a second probecard can be used. The second probecard is a fully populated probecard that includes output probes for each output pad of the memory. Data read from the memory is not compared and compressed, but output to a tester via the output pads and the output probes of the fully populated probecard. However, the cost of fully populated probecards is prohibitive and different software programs must be written for each of the two probecards.

For these and other reasons there is a need for the present invention.

### SUMMARY

One embodiment described in the disclosure provides an integrated circuit including an array of memory cells, a control circuit, and an output circuit. The array of memory cells is configured to provide a group of data bits. The control circuit is configured to provide a test mode signal. The output circuit is configured to receive the test mode signal and the group of data bits, where the output circuit selectively outputs smaller subsets of the group of data bits based on the test mode signal.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a test system.

FIG. 2 is a diagram illustrating one embodiment of an output circuit.

FIG. 3 is a diagram illustrating one embodiment of an output circuit that selects each of four smaller subsets of a group of data bits via the test mode signal.

FIG. 4 is a diagram illustrating one embodiment of an output circuit that does not receive compressed pass/fail bits.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

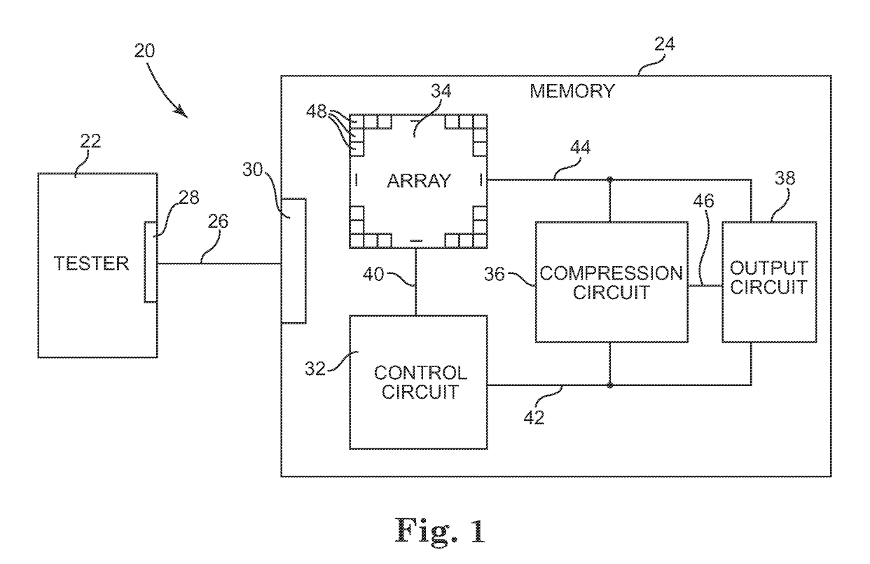

FIG. 1 is a diagram illustrating one embodiment of a test system 20 that includes a tester 22 and a device under test, memory 24. Tester 22 is electrically coupled to memory 24 via memory communications path 26. Tester 22 and memory 24 communicate data via memory communications path 26 to test memory 24. In one embodiment, tester 22 includes a micro-processor. In one embodiment, memory 24 is a DRAM. In one embodiment, memory 24 is a LP-SDRAM. In one embodiment, memory 24 is a low power mobile RAM. In one embodiment, memory 24 is a PSRAM. In one embodiment, memory 24 is a CellularRAM. In other embodiments, memory 24 is a suitable memory device under test.

Tester 20 includes input/output (I/O) circuits 28 and memory 24 includes I/O pads 30. Tester I/O circuits 28 are electrically coupled to memory I/O pads 30 via memory communications path 26. In one embodiment, memory communications path 26 includes a probecard that has probes electrically coupled to I/O pads 30.

Memory 24 is configured to output the data bits in a group of data bits to a smaller number of I/O pads 30 than the number of data bits in the group of data bits. Also, memory 24 is configured to output the compressed pass/fail bits for the group of data bits to the same I/O pads 30.

Memory 24 includes a control circuit 32, an array of memory cells 34, a compression circuit 36, and an output circuit 38. Control circuit 32 is electrically coupled to the array of memory cells 34 via array signal path 40, and control circuit 32 is electrically coupled to compression circuit 36 and output circuit 38 via control signal path 42. The array of memory cells 34 is electrically coupled to compression circuit 36 and output circuit 38 via data path 44. Compression circuit 36 is electrically coupled to output circuit 38 via pass/fail data path 46. Also, control circuit 32 and output circuit 38 are electrically coupled to I/O pads 30 via I/O signal paths (not shown for clarity).

The array of memory cells 34 includes memory cells 48. In one embodiment, memory cells 48 are DRAM memory cells. In one embodiment, memory 24 is a low power mobile RAM and memory cells 48 are DRAM memory cells. In one embodiment, memory 24 is a CellularRAM and memory cells 48 are DRAM memory cells.

Memory 24 receives addresses and commands, including test commands, from tester 22 via memory communications path 26 and I/O pads 30. Control circuit 32, which controls testing of memory 24 and the array of memory cells 34, receives the test commands and writes test data into the array of memory cells 34 via array signal path 40. The array of memory cells 34 stores the test data and control circuit 32 reads the test data from the array of memory cells 34. Data read from the array of memory cells 34 is provided in groups of data bits, such as 16 data bits at a time. Compression circuit 36 and output circuit 38 receive the groups of data bits via data path 44.

Control circuit 32 and/or compression circuit 36 compares data read from the array of memory cells 34 to data written into the array of memory cells 34 to obtain test results. Compression circuit 36 compresses the test results into a smaller number of pass/fail bits for each group of data bits. Output circuit 38 receives the smaller number of pass/fail bits via pass/fail data path 46. In one embodiment, each group of 16 data bits is compressed to four pass/fail bits.

Control circuit 32 provides a test mode signal and a test mode compression signal via control signal path 42. The test mode compression signal indicates whether memory 24 is in compressed test result mode. The test mode signal and the test mode compression signal are used to select between subsets of a group of data bits and the pass/fail bits for the group of data bits. Each subset of the group of data bits has a smaller number of bits than the number of bits in the group of data bits. Also, each bit in the group of data bits is in one of the smaller subsets of the group of data bits. In one embodiment, each 16 bit group of data bits is divided into four smaller subsets of four data bits each.

Output circuit 38 receives the test mode signal, the test mode compression signal, the groups of data bits, and the pass/fail bits. Output circuit 38 selectively outputs one of the smaller subsets of a group of data bits or the pass/fail bits for the group of data bits based on the test mode signal and the test mode compression signal. In one embodiment, output circuit 38 selectively outputs smaller subsets of a group of data bits and the pass/fail bits based on the test mode signal. In one embodiment, output circuit selectively outputs each of the smaller subsets of a group of data bits based on the test mode signal. In one embodiment, output circuit 38 selectively outputs one of the smaller subsets of a group of data bits and the pass/fail bits based on the test mode compression signal.

Also, output circuit 38 selectively outputs the smaller subsets of a group of data bits and the pass/fail bits for the group of data bits to a group or set of I/O pads 30 that is smaller in number than the number of data bits in the group of data bits. In one embodiment, each smaller subset has the same number of bits as the smaller number of pass/fail bits. In one embodiment, output circuit 38 selectively outputs each of the smaller subsets of the group of data bits and the pass/fail bits of the group of data bits to a set of I/O pads 30 that is equal in number to the smaller number of pass/fail bits.

In other embodiments, the memory does not include a compression circuit, such as compression circuit 36. The control circuit provides a test mode signal that is used to select between the smaller subsets of a group of data bits. The output circuit selectively outputs each of the smaller subsets of the group of data bits based on the test mode signal. The output circuit selectively outputs the smaller subsets of the group of data bits to a set of I/O pads that is smaller in number than the number of data bits in a group of data bits.

Output circuit 38 is configured to output the smaller subsets of a group of data bits and the pass/fail bits of the group of data bits to a smaller number of I/O pads 30 than the number of data bits in the group of data bits. Also, output circuit 38 is configured to output all of the data bits in the group of data bits to the smaller number of I/O pads 30 via the smaller subsets of data bits. Using a smaller number of I/O pads 30 increases the number of memories that can be tested in parallel. In addition, the same probecard can be used for testing via compressed test results and for testing to obtain failed data bit locations, which obviates the need for a second probecard that is fully populated and reduces the software programming burden.

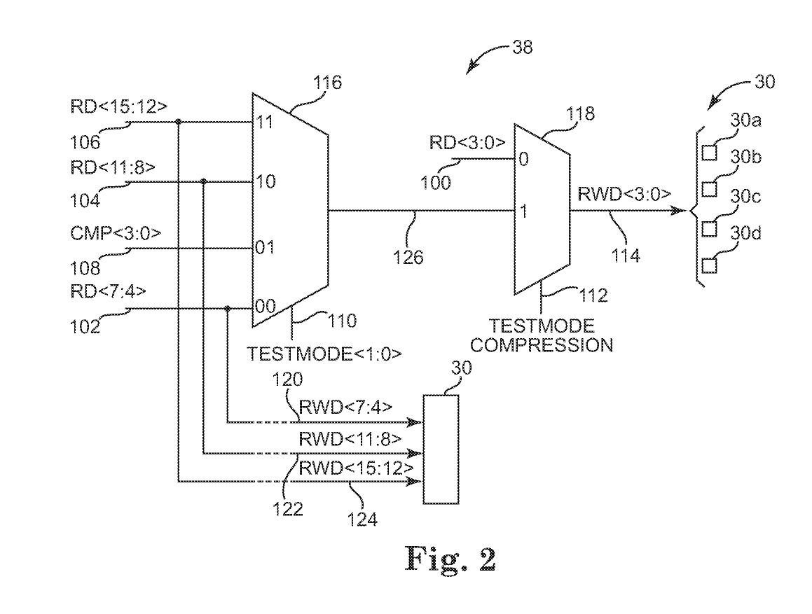

FIG. 2 is a diagram illustrating one embodiment of output circuit 38 that receives 16 data bits in each group of data bits read from the array of memory cells 34. The 16 data bits are received in four smaller subsets of four data bits each, including read data bits RD <3:0> at 100, read data bits RD <7:4> at 102, read data bits RD <8:11> at 104, and read data bits RD <15:12> at 106. In addition, output circuit 38 receives four compressed pass/fail bits CMP <3:0> at 108, the test mode signal <1:0> at 110 and the test mode compression signal at 112. Output circuit 38 provides four data bits to read/write data lines RWD <3:0> at 114.

Output circuit 38 includes a first multiplexer 116, a second multiplexer 118, and I/O pads 30. Read data bits RD <7:4> at 102 are electrically coupled to read/write data lines RWD <7:4> at 120, read data bits RD <8:11> at 104 are electrically coupled to read/write data lines RWD <11:8> at 122, and read data bits RD <15:12> at 106 are electrically coupled to read/write data lines RWD <15:12> at 124. Read/write data lines RWD <15:4> at 120, 122 and 124 are electrically coupled to I/O pads 30. Read/write data lines RWD <3:0> at 114 are electrically coupled to I/O pads 30a-30d. In one embodiment, RWD <0> is electrically coupled to I/O pad 30a, RWD <1> is electrically coupled to I/O pad 30b, RWD <2> is electrically coupled to I/O pad 30c, and RWD <3> is electrically coupled to I/O pad 30d.

First multiplexer 116 receives read data bits RD <7:4> at 102, read data bits RD <8:11> at 104, and read data bits RD <15:12> at 106 and the four compressed pass/fail bits CMP <3:0> at 108 at data inputs. First multiplexer 116 also receives test mode signal <1:0> at 110 at its select input. The output of first multiplexer 116 is electrically coupled to one of the inputs of second multiplexer 118 via multiplexer signal path 126. Second multiplexer 118 receives read data bits RD <3:0> at 100 and the output of first multiplexer 116 at data inputs, and the test mode compression signal at 112 at its select input.

In normal operation, the test mode compression signal at 112 is a low logic level 0 and second multiplexer 118 selects read data bits RD <3:0> at 100. The read data bits RD <3:0> at 100 are provided to read/write data lines RWD <3:0> at 114 and output on I/O pads 30a-30d. Also, read data bits RD <7:4> at 102, read data bits RD <8:11> at 104, and read data bits RD <15:12> at 106 are output to I/O pads 30 via read/write data lines RWD <7:4> at 120, read/write data lines RWD <11:8> at 122, and read/write data lines RWD <15:12> at 124, respectively. The 16 data bits in each group of data bits are output to 16 different I/O pads 30.

In a test mode operation for identifying failed data bit locations, the test mode compression signal at 112 is set to a low logic level 0 to select and output read data bits RD <3:0> at 100. The read data bits RD <3:0> at 100 are provided to read/write data lines RWD <3:0> at 114 and output via I/O pads 30a-30d. To output the other read data bits RD <15:4> at 102, 104 and 106, the test mode compression signal at 112 is set to a high logic level 1 to select the output of first multiplexer 116. The test mode signal at 110 is set to 00 to output read data bits RD <7:4> at 102, where second multiplexer 118 receives read data bits RD <7:4> at 102 via the output of first multiplexer 116 and provides read data bits RD <7:4> at 102 to read/write data lines RWD <3:0> at 114 and I/O pads 30a-30d. The test mode signal at 110 is set to 10 to output read data bits RD <11:8> at 104, where second multiplexer 118 receives read data bits RD <11:8> at 104 via the output of first multiplexer 116 and provides read data bits RD <11:8> at 104 to read/write data lines RWD <3:0> at 114 and I/O pads 30a-30d. The test mode signal at 110 is set to 11 to output read data bits RD <15:12> at 106, where second multiplexer 118 receives read data bits RD <15:12> at 106 via the output of first multiplexer 116 and provides read data bits RD <15:12> at 106 to read/write data lines RWD <3:0> at 114 and I/O pads 30a-30d.

In compression test mode operation, the test mode compression signal at 112 is set to a high logic level 1 to select the output of first multiplexer 116. The test mode signal at 110 is set to 01 to output the four compressed pass/fail bits CMP <3:0> at 108. Second multiplexer 118 receives the four compressed pass/fail bits CMP <3:0> at 108 via the output of first multiplexer 116 and provides the four compressed pass/fail bits CMP <3:0> at 108 to read/write data lines RWD <3:0> at 114 and I/O pads 30a-30d.

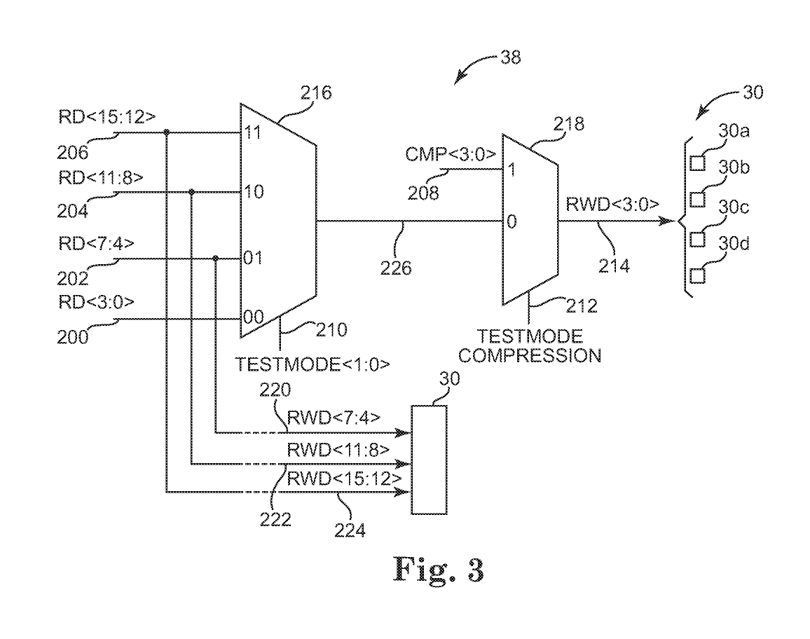

FIG. 3 is a diagram illustrating one embodiment of output circuit 38 that selects each of four smaller subsets of a group of data bits via the test mode signal. Output circuit 38 receives 16 data bits in each group of data bits read from the array of memory cells 34. The 16 data bits are received in the four smaller subsets of four data bits each, including read data bits RD <3:0> at 200, read data bits RD <7:4> at 202, read data bits RD <8:11> at 204, and read data bits RD <15:12> at 206. In addition, output circuit 38 receives four compressed pass/fail bits CMP <3:0> at 208, the test mode signal <1:0> at 210 and the test mode compression signal at 212. Output circuit 38 provides four data bits to read/write data lines RWD <3:0> at 214.

Output circuit 38 includes a first multiplexer 216, a second multiplexer 218, and I/O pads 30. Read data bits RD <7:4> at 202 are electrically coupled to read/write data lines RWD <7:4> at 220, read data bits RD <8:11> at 204 are electrically coupled to read/write data lines RWD <11:8> at 222, and read data bits RD <15:12> at 206 are electrically coupled to read/write data lines RWD <15:12> at 224. Read/write data lines RWD <15:4> at 220, 222 and 224 are electrically coupled to I/O pads 30. Also, read/write data lines RWD <3:0> at 214 are electrically coupled to I/O pads 30a-30d. In one embodiment, RWD <0> is electrically coupled to I/O pad 30a, RWD <1> is electrically coupled to I/O pad 30b, RWD <2> is electrically coupled to I/O pad 30c, and RWD <3> is electrically coupled to I/O pad 30d.

First multiplexer 216 receives read data bits RD <3:0> at 200, read data bits RD <7:4> at 202, read data bits RD <8:11> at 204, and read data bits RD <15:12> at 206 at data inputs. First multiplexer 216 also receives test mode signal <1:0> at 210 at its select input. The output of first multiplexer 216 is electrically coupled to one of the inputs of second multiplexer 218 via multiplexer signal path 226. Second multiplexer 218 receives the four compressed pass/fail bits CMP <3:0> at 208 and the output of first multiplexer 216 at data inputs, and the test mode compression signal at 212 at its select input.

In normal operation, the test mode signal at 210 is set to 00 and the test mode compression signal at 212 is set to a low logic level 0. First multiplexer 216 selects read data bits RD <3:0> at 200 and second multiplexer 218 selects the output of first multiplexer 218. The read data bits RD <3:0> at 200 are provided to read/write data lines RWD <3:0> at 214 and output on I/O pads 30a-30d. Also, read data bits RD <7:4> at 202, read data bits RD <8:11> at 204, and read data bits RD <15:12> at 206 are output to I/O pads 30 via read/write data lines RWD <7:4> at 220, read/write data lines RWD <11:8> at 222, and read/write data lines RWD <15:12> at 224, respectively. The 16 data bits in each group of data bits are output to 16 different I/O pads 30.

In a test mode operation for identifying failed data bit locations, the test mode compression signal at 212 is set to a low logic level 0 to select the output of first multiplexer 216. The test mode signal at 210 is set to 00 to output read data bits RD <3:0> at 200, where second multiplexer 218 receives read data bits RD <3:0> at 200 via the output of first multiplexer 216 and provides read data bits RD <3:0> at 200 to read/write data lines RWD <3:0> at 214 and I/O pads 30a-30d. The test mode signal at 210 is set to 01 to output read data bits RD <7:4> at 202, where second multiplexer 218 receives read data bits RD <7:4> at 202 via the output of first multiplexer 216 and provides read data bits RD <7:4> at 202 to read/write data lines RWD <3:0> at 214 and I/O pads 30a-30d. The test mode signal at 210 is set to 10 to output read data bits RD <11:8> at 204, where second multiplexer 218 receives read data bits RD <11:8> at 204 via the output of first multiplexer 216 and provides read data bits RD <11:8> at 204 to read/write data lines RWD <3:0> at 214 and I/O pads 30a-30d. The test mode signal at 210 is set to 11 to output read data bits RD <15:12> at 206, where second multiplexer 218 receives read data bits RD <15:12> at 206 via the output of first multiplexer 216 and provides read data bits RD <15:12> at 206 to read/write data lines RWD <3:0> at 214 and I/O pads 30a-30d.

In compression test mode operation, the test mode compression signal at 212 is set to a high logic level 1 to select the four compressed pass/fail bits CMP <3:0> at 208. Second multiplexer 218 receives the four compressed pass/fail bits CMP <3:0> at 208 and provides the four compressed pass/fail bits CMP <3:0> at 208 to read/write data lines RWD <3:0> at 214 and I/O pads 30a-30d.

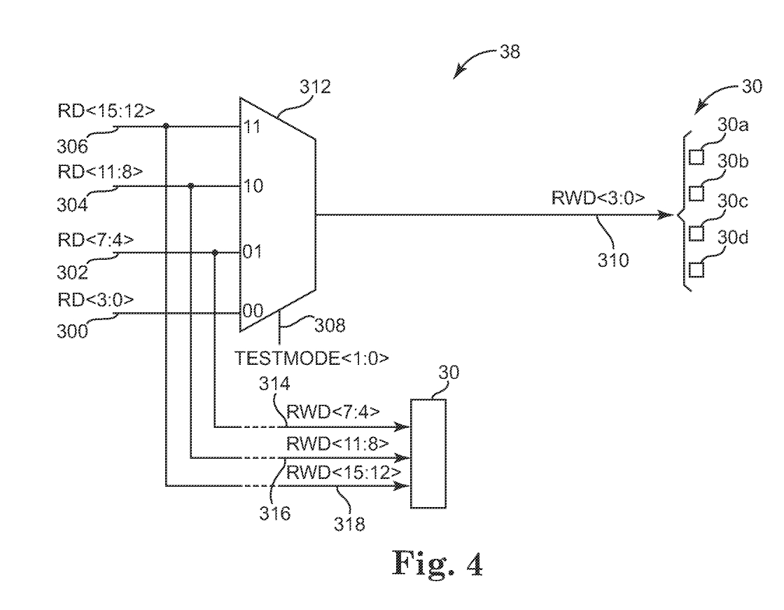

FIG. 4 is a diagram illustrating one embodiment of output circuit 38 that does not receive compressed pass/fail bits. Output circuit 38 receives 16 data bits in each group of data bits read from the array of memory cells 34. The 16 data bits are received in the four smaller subsets of four data bits each, including read data bits RD <3:0> at 300, read data bits RD <7:4> at 302, read data bits RD <8:11> at 304, and read data bits RD <15:12> at 306. In addition, output circuit 38 receives the test mode signal <1:0> at 308. Output circuit 38 provides four data bits to read/write data lines RWD <3:0> at 310.

Output circuit 38 includes a first multiplexer 312 and I/O pads 30. Read data bits RD <7:4> at 302 are electrically coupled to read/write data lines RWD <7:4> at 314, read data bits RD <8:11> at 304 are electrically coupled to read/write data lines RWD <11:8> at 316, and read data bits RD <15:12> at 306 are electrically coupled to read/write data lines RWD <15:12> at 318. Read/write data lines RWD <15:4> at 314, 316 and 318 are electrically coupled to I/O pads 30. Also, read/write data lines RWD <3:0> at 310 are electrically coupled to I/O pads 30a-30d. In one embodiment, RWD <0> is electrically coupled to I/O pad 30a, RWD <1> is electrically coupled to I/O pad 30b, RWD <2> is electrically coupled to I/O pad 30c, and RWD <3> is electrically coupled to I/O pad 30d.

First multiplexer 312 receives read data bits RD <3:0> at 300, read data bits RD <7:4> at 302, read data bits RD <8:11> at 304, and read data bits RD <15:12> at 306 at data inputs. First multiplexer 312 also receives test mode signal <1:0> at 308 at its select input. The output of first multiplexer 312 is electrically coupled to read/write data lines RWD <3:0> at 310.

In normal operation, the test mode signal at 308 is set to 00. First multiplexer 312 selects read data bits RD <3:0> at 300. The read data bits RD <3:0> at 300 are provided to read/write data lines RWD <3:0> at 310 and output on I/O pads 30a-30d. Also, read data bits RD <7:4> at 302, read data bits RD <8:11> at 304, and read data bits RD <15:12> at 306 are output to I/O pads 30 via read/write data lines RWD <7:4> at 314, read/write data lines RWD <11:8> at 316, and read/write data lines RWD <15:12> at 318, respectively. The 16 data bits in each group of data bits are output to 16 different I/O pads 30.

In a test mode operation for identifying failed data bit locations, the test mode signal at 308 is set to 00 to output read data bits RD <3:0> at 300, which are provided to read/write data lines RWD <3:0> at 310 and I/O pads 30a-30d. The test mode signal at 308 is set to 01 to output read data bits RD <7:4> at 302, which are provided to read/write data lines RWD <3:0> at 310 and I/O pads 30a-30d. The test mode signal at 308 is set to 10 to output read data bits RD <11:8> at 304, which are provided to read/write data lines RWD <3:0> at 310 and I/O pads 30a-30d. The test mode signal at 308 is set to 11 to output read data bits RD <15:12> at 306, which are provided to read/write data lines RWD <3:0> at 310 and I/O pads 30a-30d.

Output circuit 38 is configured to output each of the smaller subsets of a group of data bits to a smaller number of I/O pads 30 than the number of data bits in the group of data bits. Using a smaller number of I/O pads 30 increases the number of memories that can be tested in parallel. In addition, the same probecard can be used for testing via compressed test results and for testing to obtain failed data bit locations.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
an array of memory cells configured to provide a group of data bits;
a control circuit configured to provide a test mode signal; and
an output circuit configured to receive the test mode signal and the group of data bits, wherein the output circuit selectively outputs smaller subsets of the group of data bits based on the test mode signal.

2. The integrated circuit of claim 1, comprising:
a compression circuit configured to compress the group of data bits into pass/fail bits.

3. The integrated circuit of claim 2, wherein the output circuit selectively outputs the pass/fail bits based on the test mode signal.

4. The integrated circuit of claim 2, wherein the control circuit provides a test mode compression signal and the output circuit selectively outputs the smaller subsets of the group of data bits and the pass/fail bits based on the test mode compression signal.

5. The integrated circuit of claim 1, wherein the output circuit comprises:
a first multiplexer configured to receive the test mode signal and at least some of the smaller subsets of the group of data bits and the first multiplexer selects between the at least some of the smaller subsets based on the test mode signal.

6. The integrated circuit of claim 5, comprising:
a compression circuit configured to compress the group of data bits into pass/fail bits, wherein the first multiplexer receives the pass/fail bits and selects the pass/fail bits based on the test mode signal.

7. The integrated circuit of claim 5, comprising:
a compression circuit configured to compress the group of data bits into pass/fail bits, wherein the control circuit provides a test mode compression signal and the output circuit comprises:
a second multiplexer configured to receive the test mode compression signal and select between outputs of the first multiplexer and the pass/fail bits based on the test mode compression signal.

8. The integrated circuit of claim 5, comprising:
a compression circuit configured to compress the group of data bits into pass/fail bits, wherein the control circuit provides a test mode compression signal and the output circuit comprises:
a second multiplexer configured to receive the test mode compression signal and select between one smaller subset of the group of data bits and outputs of the first multiplexer based on the test mode compression signal.

9. A memory, comprising:
input/output pads;
an array of memory cells configured to provide a group of data bits;
a compression circuit configured to compress the group of data bits into a smaller group of pass/fail bits;
an output circuit configured to receive the group of data bits and the smaller group of pass/fail bits; and
a control circuit configured to select between the smaller group of pass/fail bits and smaller subsets of the group of data bits, wherein the output circuit selectively outputs the smaller group of pass/fail bits and each of the smaller subsets of the group of data bits to a set of the input/output pads that is equal in number to the smaller group of pass/fail bits.

10. The memory of claim 9, wherein the control circuit provides a test mode signal and the output circuit selectively outputs the smaller group of pass/fail bits based on the test mode signal.

11. The memory of claim 9, wherein the control circuit provides a test mode signal and the output circuit selectively outputs each of the smaller subsets of the group of data bits based on the test mode signal.

12. The memory of claim 9, wherein the control circuit provides a test mode signal and the output circuit comprises:
a first multiplexer configured to receive the test mode signal and at least some of the smaller subsets of the group of data bits, wherein the first multiplexer selects between the at least some of the smaller subsets of the group of data bits based on the test mode signal.

13. The memory of claim 12, wherein the control circuit provides a test mode compression signal and the output circuit comprises:
a second multiplexer configured to receive the test mode compression signal and select between outputs of the first multiplexer and the pass/fail bits based on the test mode compression signal.

14. The memory of claim 12, wherein the control circuit provides a test mode compression signal and the output circuit comprises:
a second multiplexer configured to receive the test mode compression signal and select between one smaller subset of the group of data bits and outputs of the first multiplexer based on the test mode compression signal.

15. An integrated circuit comprising:
means for storing a group of data bits;
means for providing a test mode signal and controlling testing of the means for storing;
means for receiving the test mode signal and the group of data bits; and
means for selectively outputting smaller subsets of the group of data bits based on the test mode signal.

16. The integrated circuit of claim 15, comprising:
means for compressing the group of data bits into pass/fail bits.

17. The integrated circuit of claim 16, wherein the means for selectively outputting comprises:
means for selectively outputting the pass/fail bits based on the test mode signal.

18. A method of testing an integrated circuit comprising:
storing a group of data bits;
providing a test mode signal;
receiving the test mode signal and the group of data bits at an output circuit;
selecting smaller subsets of the group of data bits based on the test mode signal; and
outputting the selected smaller subsets of the group of data bits.

19. The method of claim 18, comprising:
compressing the group of data bits into pass/fail bits.

20. The method of claim 19, wherein:
selecting comprises selecting the pass/fail bits based on the test mode signal; and
outputting comprises outputting the selected pass/fail bits.

21. The method of claim 19, comprising:
providing a test mode compression signal, wherein:
selecting comprises selecting the smaller subsets of the group of data bits and the pass/fail bits based on the test mode compression signal; and
outputting comprises outputting the selected smaller subsets of the group of data bits and the pass/fail bits.

22. The method of claim 18, wherein receiving the test mode signal comprises:
receiving the test mode signal and at least some of the smaller subsets of the group of data bits at a first multiplexer.

23. The method of claim 22, comprising:
compressing the group of data bits into pass/fail bits;
receiving a test mode compression signal at a second multiplexer; and
selecting comprises selecting between outputs of the first multiplexer and the pass/fail bits based on the test mode compression signal.

24. The method of claim 22, comprising:
compressing the group of data bits into pass/fail bits;
receiving a test mode compression signal at a second multiplexer; and
selecting comprises selecting between one smaller subset of the group of data bits and outputs of the first multiplexer based on the test mode compression signal.

25. A method of testing a memory, comprising:
communicating with the memory via input/output pads;
storing a group of data bits in the memory;
compressing the group of data bits into a smaller group of pass/fail bits;
receiving the group of data bits and the smaller group of pass/fail bits at an output circuit;
selecting between the smaller group of pass/fail bits and smaller subsets of the group of data bits; and
outputting selectively the smaller group of pass/fail bits and each of the smaller subsets of the group of data bits to a set of the input/output pads that is equal in number to the smaller group of pass/fail bits.
